(19) United States
(12) Patent Application Publication
(10) Pub. No.: US 2007/0102625 A1
(43) Pub. Date: May 10, 2007

(54) Light-receiving diode

(75) Inventors: Wei Chang, San Chung City (TW); Tsung-Wei Lin, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/267,508

(22) Filed: Nov. 7, 2005

(51) Int. Cl. H01L 31/00

(52) U.S. Cl. 250/214.1

(57) ABSTRACT

A light-receiving diode comprises: a bearing frame on which a light-receiving chip, a SMD capacitor, and a transimpedance amplifier are mounted; a plurality of pins, wherein the bearing frame is coupled to one of the pins and the light-receiving chip is connected to the other pins via a plurality of conducting lines; and an encapsulated resin for packaging the above-mentioned components and upper ends of the pins. As a result, the production cost can be reduced effectively.

### FIELD OF THE INVENTION

The present invention relates to a light-receiving diode or a similar device capable of simplifying manufacturing procedure and significantly saving production cost.

### BACKGROUND OF THE INVENTION

In the current fiber system, the laser diodes have been adopted as the light sources. The laser diodes form the laser diode devices after they are packaged. As shown in FIG. 5, the conventional VCSEL (Vertical Cavity Surface Emitting Laser) device requires a large-area base A and three pins are connected to the bottom of the base A. Besides, a mounting device B, a photodiode chip C, and a VCSEL chip D are attached to the base A in sequence, and a metal cover E having a lens E1 is further applied to cover them.

The light-receiving diode and the laser diode have approximately identical structure. The difference between them is that a light-receiving chip replaces the VCSEL chip D. Referring to FIG. 6, when being applied to transmit fiber signals, the laser diode device 1 is mounted inside a metal base 2 and steadily fixed by a fixing adhesive 3. A fixing sleeve 4 is steadily coupled to the metal base 2. A hollow ceramic tube 5 is coaxially mounted inside the sleeve 4. A cylindrical ceramic head 6 is coaxially mounted inside the ceramic tube 5, wherein the rear end of the ceramic head 6 is polished to form a slanted flat surface 7 to prevent the light from being reflected back toward the laser diode directly. As a result, the laser diode is free from interference by noise.

In addition, a fiber 8 is coaxially mounted inside the ceramic head 6 so as to exactly gather the light emitted from the laser diode device 1 into a fiber core of the fiber 8. Moreover, the sleeve 4 can be coupled to a fiber connector, and the parallel beams that travel within the fiber core of the fiber 8 are then guided to the fiber core of the fiber 8 of the fiber connector. The assembly of the foregoing components completes a light-emitting module. Alternatively, a light-receiving module can be formed by replacing the above-mentioned laser diode device 1 with a photodetector.

The light-receiving diode is designed for merely receiving signals so it will not causes too much heat. The light-receiving diode and the laser diode device that sends signals are approximately identical in assembled structure. Therefore, the light-receiving diode also requires the processes of providing the large-area base A and the metal cover E. As a result, the major deficiency consists in that the conventional structure increases production cost and complicates manufacturing procedure.

In view of the aforementioned conventional deficiency, the present inventor makes a diligent study to provide the consumer with a light-receiving diode capable of simplifying manufacturing procedure and saving production cost in accordance with the motive of the present invention.

### SUMMARY OF THE INVENTION

It is a main objective of the present invention to disclose a light-receiving diode capable of effectively simplifying manufacturing procedure and significantly saving production cost.

In order to achieve the aforementioned objective, a light-receiving diode comprises: a bearing frame on which a light-receiving chip, a SMD capacitor, and a transimpedance amplifier are mounted; a plurality of pins, wherein the bearing frame is coupled to one of the pins and the light-receiving chip is connected to the other pins via a plurality of conducting lines; and an encapsulated resin for packaging the above-mentioned components and upper ends of the pins. As a result, the production cost can be reduced effectively.

The aforementioned aspects and advantages of the present invention will be readily clarified in the description of the preferred embodiments and the enclosed drawings of the present invention.

### BRIEF DESCRIPTION OF THE DRAWINGS

FIG. 1 is a three-dimensional view showing the structure of the present invention.

FIG. 2 is a schematic view showing that a sleeve is coupled to the structure of the present invention.

FIG. 3 is an assembled cross-sectional view of FIG. 2.

FIG. 4 is a schematic view showing the application of the present invention.

FIG. 5 is a cross-sectional view showing the conventional light-emitting module.

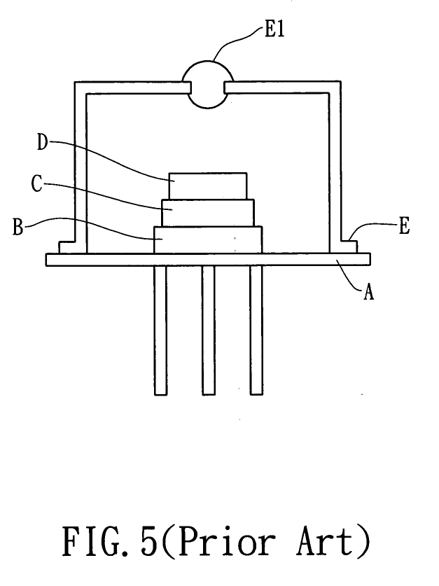

FIG. 6 is a schematic view showing the application of the conventional light-emitting module.

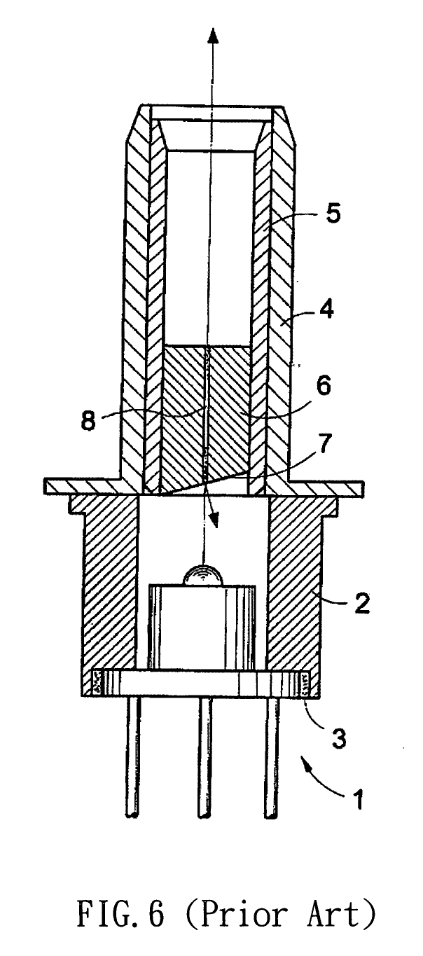

### DETAILED DESCRIPTION OF THE PREFERRED EMBODIMENT

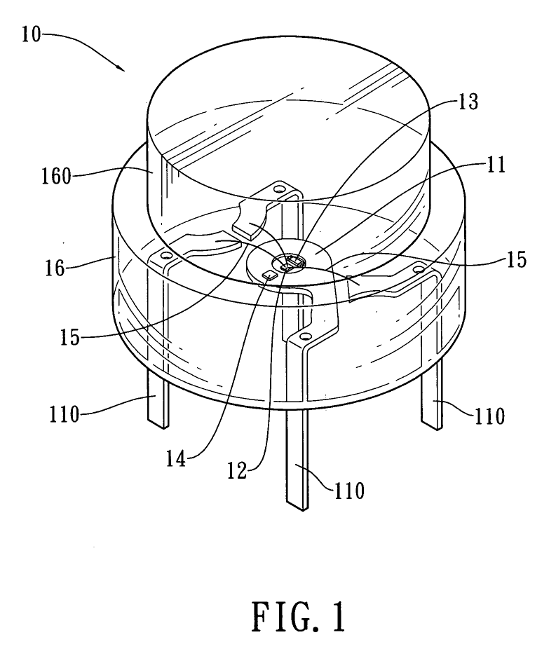

Referring to FIG. 1, the light-receiving diode 10 of the present invention comprises a bearing frame 11 and a plurality of pins 110, wherein a chip base to which a light-receiving chip 12 and a SMD capacitor 13 are attached is formed on the bearing frame 11. Besides, a transimpedance amplifier 14 is attached to the bearing frame 11 near the chip base. The light-receiving chip 12 is connected to other pins 110 via several conducting lines 15. After formation of the conducting lines 15, the upper ends of these pins 110, the conducting lines 15, the light-receiving chip 12, the SMD capacitor 13, and the transimpedance amplifier 14 are all packaged by an encapsulated resin 16 so as to complete the assembly of the light-receiving diode 10. In addition, the encapsulated resin 16 has an upwardly protrudent part 160.

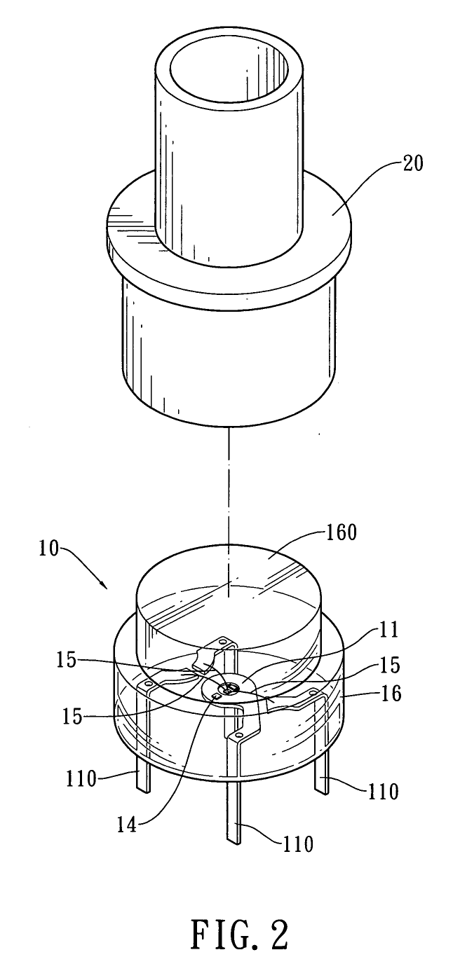

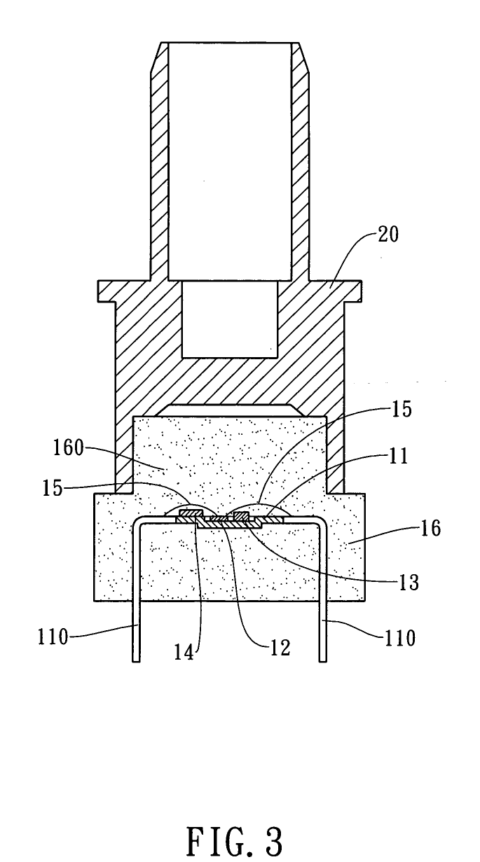

Referring to FIG. 2 and FIG. 3, the above-mentioned light-receiving diode 10 can be inserted into and coupled to a sleeve 20 directly by use of the upwardly protrudent part 160. The sleeve 20 has two different diameter sections, wherein one of these two sections has a diameter corresponding to that of the upwardly protrudent part 160. As a result, the using and coating process of the conventional metal base and fixing adhesive can be omitted.

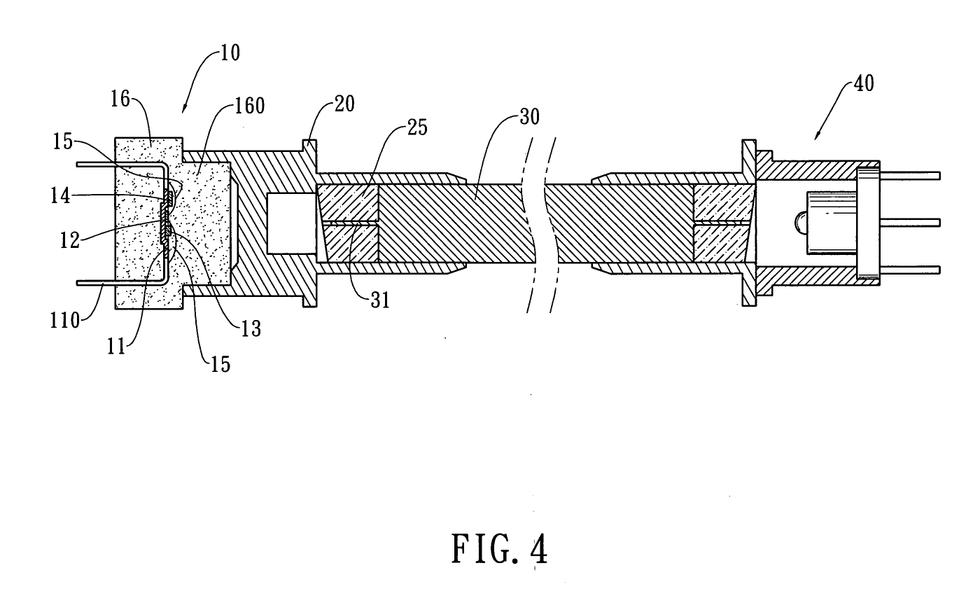

Referring to FIG. 4, the light-receiving chip 12 of the light-receiving diode 10 is located to face the center of the sleeve 20 after insertion of the upwardly protrudent part 160 into one end of the sleeve 20. A ceramic head 25 having a center through hole is inserted into the other end of the sleeve 20. Besides, a fiber 30 is coaxially connected to the ceramic head 25 by its one end. Moreover, the other end of the fiber 30 is connected to a light emitter 40. As a result, the light emitted from the light emitter 40 can be gathered into a fiber core 31 of the fiber 30 and subsequently guided to the light-receiving diode 10 via the fiber core 31.

According to the foregoing description, it is apparent that the structure of the present invention provides the following advantages, in which:

1. The light-receiving diode doesn't need to take heat dissipation problem into consideration so the encapsulated resin can be applied directly for significantly saving the cost of using the large-area base and omitting the process of inserting the conventional structure into the metal.

2. The encapsulated resin of the light-receiving diode can be coupled to the sleeve by means of its specific shape for simplifying the structure of the light-receiving module such that the production cost can be reduced significantly.

3. Because the light-receiving diode hardly produces heat, the assembled light-receiving module doesn't need to take heat dissipation problem into consideration such that the encapsulated resin can be applied directly.

In summary, the light-receiving diode of the present invention satisfies patentability. Accordingly, it is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A light-receiving diode comprising:
a bearing frame on which a light-receiving chip, a SMD capacitor, and a transimpedance amplifier are mounted;
a plurality of pins, wherein the bearing frame is mounted on one of the pins and the light-receiving chip is connected to the other pins via a plurality of conducting lines; and
an encapsulated resin for packaging the above-mentioned components and upper ends of the pins.

2. The light-receiving diode of claim 1, wherein the encapsulated resin has an upwardly protrudent part.

3. The light-receiving diode of claim 1, wherein a chip base is formed on the bearing frame for holding the light-receiving chip and the SMD capacitor.
